(19) United States
(12) Patent Application Publication
(10) Pub. No.: US 2003/0018937 A1
(43) Pub. Date: Jan. 23, 2003

(54) Method and apparatus for efficient self-test of voltage and current level testing

(76) Inventor: Atul S. Athavale, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/908,643

(22) Filed: Jul. 18, 2001

(51) Int. Cl. G01R 31/28

(52) U.S. Cl. 714/724

(57) ABSTRACT

A reference level test during a self-test mode of operation of an integrated device.

### FIELD OF THE CLAIMED SUBJECT MATTER

The present claimed subject matter relates to design for test improvements, and specifically to a method and apparatus for a self-test implementation for voltage and current level testing.

### DESCRIPTION OF THE RELATED ART

As the technology for manufacturing integrated circuits advances, more logic functions are included in a single integrated circuit device. Modern integrated circuit (IC) devices include large numbers of gates on a single semiconductor chip, with these gates interconnected so as to perform multiple and complex functions. The fabrication of an IC incorporating such Very Large Scale Integration (VLSI) must be error free, as a manufacturing defect may prevent the IC from performing all of the functions that an IC is designed to perform. Such demands require verification of the design of the IC and also various types of electrical testing after the IC is manufactured.

However, as the complexity of the IC increases, so does the cost and complexity of verifying and electrically testing each of the devices in the IC. Electrical testing ensures that each node in a VLSI circuit functions properly. Therefore, each node needs to individually, and in conjunction with the other node in the IC, function properly in all possible combinations of operations. Typically, electrical testing is performed by automated testing equipment (ATE) that employs test vectors to perform the desired tests. A test vector describes the desired test input (or signals), associated clock pulse (or pulses), and expected test output (or signals) for every package pin during a period of time, often in an attempt to “test” a particular node. For complex circuitry, this may involve a large number of test vectors and, accordingly, a long test time.

Testing costs and complexity increase dramatically because of the increasing number of functional pins on the integrated devices. One solution for reducing test costs is to use test equipment with a capability to only test a limited number of pins with a limited number of test channels. However, testing and fault coverage suffers because of the inability to control and observe various logic nodes within the integrated device due to the lack of dedicated tester channels.

One way to address this problem is through design for test (DFT). The key concepts in DFT are controllability and observability. Controllability is the ability to set and reset the state of every node in the IC. Observability is the ability to observe either directly or indirectly the state of any node in the IC. The purpose of DFT is to increase the ability to control and observe internal and external nodes from external inputs/outputs. One common DFT implementation is built in self-test (BIST) that allows for logic internal to the integrated device, to create test patterns and verify proper logic functionality of the integrated device. However, BIST has only been limited in use to logic functionality and has not been incorporated into parametric and voltage and current level testing.

### BRIEF DESCRIPTION OF THE SEVERAL VIEWS OF THE DRAWINGS

The claimed subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 illustrates a block diagram utilized by one embodiment.

FIG. 2 illustrates a flow chart utilized by one embodiment.

FIG. 3 illustrates a flow chart utilized by one embodiment.

### DETAILED DESCRIPTION OF THE CLAIMED SUBJECT MATTER

A method and apparatus for self-test implementation of voltage and current level testing. are described. In the following description, for purposes of explanation, numerous details are set forth in order to provide a thorough understanding of the claimed subject matter. However, it will be apparent to one skilled in the art that these specific details are not required in order to practice the present invention.

An area of current technological development relates to reducing test costs by utilizing low pin count testers and DFT implementations. As previously described, BIST has only been implemented for logic functionality and has not been incorporated into parametric and voltage and current level testing. Thus, implementing a more efficient method of voltage and current testing with a reduced number of test pins is desirable. In one aspect, the claimed subject matter enables the use of low pin-count automatic test equipment (ATE) for testing an integrated device's voltage and current levels to ensure compatibility with databook specifications for the integrated device. In another aspect, the claimed subject matter enables the use of a low pin-count ATE to test an integrated device with a high pin count.

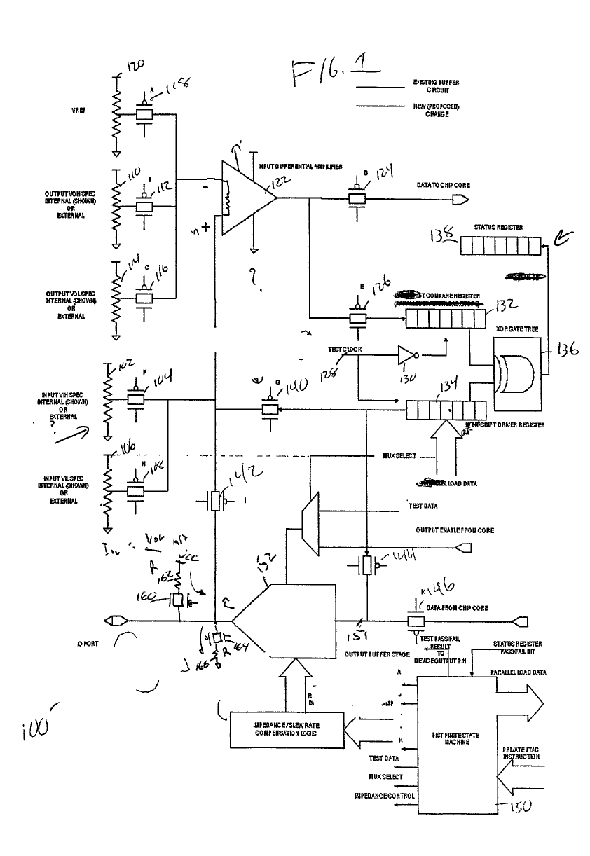

FIG. 1 illustrates an input/output buffer 100 utilized by one embodiment. The input/output buffer 100 comprises, but is not limited to, a voltage input high (VIH) reference level 102, a voltage input low (VIL) reference level 106, a voltage output high (VOH) reference level 110, a voltage output low (VOL) reference level 114, a plurality of pass gates 104, 108, 112, 116, 118, 124, 126, 140, 142, 144, and 146, 160, 164, and resistors 162 and 166. Also, the input/output buffer 100 comprises an input differential amplifier 122, a driver register 134, a compare register 132, a exclusive OR (XOR) tree 136, and a status register 138. Also, the block diagram comprises a BIST logic engine 150 and an output buffer stage 152. The compare register and driver register are enabled to receive data by a test clock 128. In one embodiment, the test clock is slower than the integrated device's main clock to allow for the capacitive loads to settle. For example, the test clock may be in a range of one eight to one twelfth the ratio of the specified frequency of the integrated device. In one embodiment, the driver register and compare register may be sixteen bits. However, the invention is not limited to sixteen bits since one skilled in the art appreciates utilizing a different number of bits based on the desired granularity of testing.

In one embodiment, the input/output buffer allows for a BIST implementation of voltage and current level testing for an integrated device. As discussed earlier, BIST has not been incorporated for voltage and current level testing. In one embodiment, the BIST logic engine 150 receives a private Joint Test Action Group (JTAG) command to initiate the testing. JTAG is well known in the art and is a standard defined by Institute of Electrical & Electronics Engineers (I.E.E.E.) 1149.1. In another embodiment, the BIST logic engine 150 receives an enable signal from a functional pin. The reference levels are equivalent to the integrated device's product specifications with respect to VIH, VIL, VOH, and VOL. The invention is not limited to utilizing or implementing the four reference levels. For example, only one, two, or three, or more than four reference levels may be implemented. For example, a circuit with an open drain implementation, such as GTL, will not require all four reference level tests. In one embodiment, the reference levels 102, 106, 110, and 114 are internal to the integrated device and are generated by a voltage divider circuit. In another embodiment, the reference levels are external to the integrated device. For example, the reference levels are formed on a test interface unit (TIU). A TIU is a hardware interface between an automatic test equipment and an integrated device to facilitate testing of the integrated device by allowing for routing of various test signals and test channels.

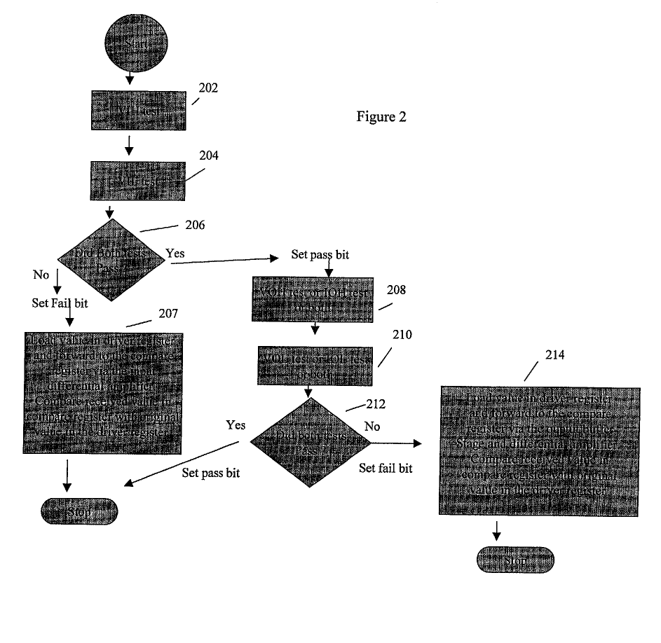

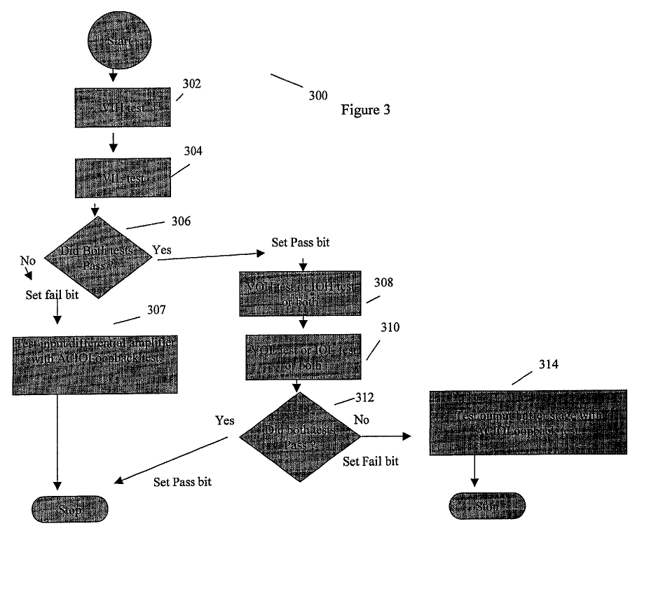

The BIST logic engine 150 generates and supervises the voltage and current levels testing. For example, in one embodiment the BIST logic engine may generate control signals to open or close the plurality of pass gates 104, 108, 112, 116, 118, 124, 126, 140, 142, 144, 146, 160, and 164. Also, the BIST logic engine 150 may generate test signatures to be loaded into the driver register 134, which is discussed further in FIGS. 2 and 3. In another embodiment, the BIST logic engine interfaces with an impedance compensation circuit 154 of the output buffer stage 152 and monitors the values of the status register 138. One skilled in the art appreciates limiting or expanding the responsibility of the BIST logic engine 150. For example, an alternative embodiment would allow the BIST logic engine 150, as a minimum, to incorporate all the previous features such as controlling the pass gates, generating test signatures, interfacing with the impedance compensation circuit, and monitoring the value of the status register. Alternatively, another embodiment would allow the BIST logic engine 150 to have only a subset of the previous features.

In one embodiment, a plurality of tests is performed to verify the functionality of the input differential amplifier 122 and the output buffer stage 152. Also, another plurality of tests is performed for testing the voltage and current level references. This is discussed further in FIG. 2. In another embodiment, a well-known DFT method of ACIO-Loopback is performed to verify the functionality of the input differential amplifier and the output buffer stage 152 and a plurality of tests is performed for testing the voltage and current level references, which is discussed further in FIG. 3.

In one embodiment, the input/output buffer 100 supports current output low (IOL) and current output high (IOH) tests. For example in one embodiment, the IOH is tested during a VOH test by coupling an end of the resistor 166 to Vss and another end of the resistor 166 to the pass gate 164. In one embodiment, the BIST logic engine 150 enables the pass gate 164 and the resistor's value is equivalent to VOH/IOH. Alternatively, the IOL is tested during a VOL test by coupling an end of the resistor 162 to Vcc and another end of the resistor 162 to the pass gate 160. In one embodiment, the BIST logic engine 150 enables the pass gate 164 and the resistor's value is equivalent to VOL/IOL.

FIG. 2 illustrates a flowchart 200 in accordance with an embodiment. The flowchart illustrates one embodiment of a sequential pattern of testing and diagnostics of an input/output buffer of an integrated device. The flowchart illustrates the flow of voltage and current level tests for input/output buffers with similar voltage and current level specifications. Thus, the flowchart needs to be repeated for input/output buffers with unique voltage and current level specifications.

The first voltage reference test is a test 202 of voltage input high (VIH) is initiated to verify the integrated device meets the specified voltage reference for VIH. As discussed earlier, the BIST logic engine 150 is initiated by a private JTAG instruction or by a functional pin. Subsequently, in one embodiment the BIST logic engine 150 loads a plurality of binary one values into the driver register 134. In one embodiment, the values are loaded in parallel into the driver register 134. In an alternative embodiment, the values are loaded serially into the driver register 134. Also, in another embodiment the driver register can be simultaneously unload while loading new values. In one embodiment, a voltage reference level of VIH is generated by a voltage divider circuit 102. Also, the voltage divider circuit 102 may be a high impedance divider circuit to minimize loading. The BIST logic engine 150 controls the pass gate 104 to allow for the VIH voltage reference 102 to be applied to an input of the input differential amplifier. Also, a voltage reference of VREF is applied to another input of the input differential amplifier. In one embodiment, an output of the input differential amplifier is sampled by a falling edge of the test clock 130 resulting in a serially shift of the sampled output into the compare register 132. Finally, after the compare register 132 is loaded, the XOR gate tree 136 performs a logic XOR (exclusive OR) operation on each corresponding bit of the compare register 132 and the driver register 134 and stores the resulting value in the status register 138. For example, if the corresponding bits in the driver register and compare register are both binary one values, then an exclusive OR operation on both the bits results in a zero binary value being stored in the status register. Thus, in one embodiment, a pass condition is a zero binary value being stored in the status register. Alternatively, if either bit in the compare or driver register are a binary zero value, this results in a binary one value being stored in the status register, which indicates a fail condition. In one embodiment, the result of the XOR operation is compressed and stored in the status register.

Continuing on with the next test, a test 204 of voltage input low (VIL) is initiated to verify the integrated device meets the specified voltage reference for VIL. In one embodiment, the VIL test is similar to the previously discussed VIH test except for a few changes. For example, a different voltage divider circuit 106 is utilized to generate the voltage reference and a different pass gate 108 is utilized to allow the voltage reference to be forwarded to an input of the input differential amplifier 122. Also, the sampled output from the input differential amplifier 122 is inverted before being loaded into the compare register 132. However, if the driver register was initially loaded with a plurality of binary zero values, then the sampled output from the input differential amplifier 122 is not inverted before being loaded into the compare register 132.

After the VIH test 202 and the VIL test 204 are completed, a comparison test 206 is performed to determine whether both tests result in a pass condition. As previously discussed, in one embodiment, a binary zero value for a bit stored in the status register indicates a pass condition. Alternatively, a binary one value for a bit stored in the status register indicates a fail condition. If both tests result in a pass condition, a pass bit is enabled and a voltage reference test for voltage output high (VOH) 208 is initiated. Alternatively, if either test results in a fail condition, a fail bit is enabled and a diagnostic test 207 is initiated. In one embodiment, the diagnostic test is initiated by the BIST logic engine 150 loading an alternating binary signature of a binary one and a binary zero value into the driver register. Subsequently, the driver register is serially unloaded at a rising edge of the test clock 128 and applied to an input of the input differential amplifier 122 via the pass gate 140. The output of the input differential amplifier is sampled at the falling edge of the test clock and loaded into the compare register via the pass gate 122. Finally, a XOR operation on each corresponding bit of the compare register and driver register is performed and the result is stored in the status register. Thus, the existence of a pass condition for every bit of the status register indicates the absence of any gross stuck at faults in the input stage of the block diagram 100. Also, the input/output buffer 100 fails either or both of the VIH and VIL specifications.

As previously discussed, the VOH test 208 is initiated if both VIH test 202 and VIL test 204 passed. In one embodiment, the BIST logic engine 150 loads in parallel a binary one value into every bit of the driver register. In another embodiment, the BIST logic engine 150 serially loads a binary one value into every bit of the driver register. Subsequently, the driver register forwards the stored values of binary ones to an input node 151 of the output buffer stage 152 via a pass gate 144. As discussed earlier, in one embodiment the pass gates are enabled by the BIST logic engine 150. The BIST logic engine 150 controls and instructs an impedance/slew rate compensation logic 154 to set the appropriate impedance values to enable the output buffer stage to forward the value stored on the input node 151 to an input of the input differential amplifier 122. Also, the BIST logic engine enables a voltage reference VOH from a voltage divider circuit 110 to be applied to another input of the input differential amplifier via the pass gate 112. The output of the input differential amplifier 122 is sampled on the falling edge of the test clock and serially shifted into the compare register. Subsequently, an exclusive OR (XOR) operation is performed on each corresponding bit of the compare register and driver register and the result is stored in the status register. In one embodiment, the result is compressed in the status register. As previously discussed for one embodiment, a binary zero value for a bit stored in the status register indicates a pass condition. Alternatively, a binary one value for a bit stored in the status register indicates a fail condition.

In one embodiment, the VOH test may be supplemented with an IOH test by the BIST logic engine enabling resistor 166 by enabling pass gate 164. In another embodiment, only the VOH test is performed and either the input/output buffer 100 does not have a resistor 166 or the resistor 166 is disabled.

After the completion of the VOH test 208, a VOL test 210 is initiated to verify the integrated device meets the specified voltage reference for voltage output low (VOL). In one embodiment, the VOL test is similar to the previously discussed VOH test except for a few changes. For example, one change is the BIST logic engine loads binary zero values, rather than binary one values for the VOH test, into the driver register and a different voltage divider circuit 114 is coupled to an input of the input differential amplifier 122 via the pass gate 116. Also, in one embodiment, the VOL test is supplemented with an IOL test by the BIST logic engine enabling resistor 162 by enabling pass gate 160. In another embodiment, only the VOL test is performed and either the input/output buffer 100 does not have a resistor 162 or the resistor 162 is disabled.

After the VOH test 208 and the VOL test 210 are completed, a comparison test 212 is performed to determine whether both tests result in a pass condition. As previously discussed, in one embodiment, a binary zero value for a bit stored in the status register indicates a pass condition. Alternatively, a binary one value for a bit stored in the status register indicates a fail condition. If both tests result in a pass condition, then the output buffer stage is verified to be functional. Alternatively, if either test results in a fail condition, a diagnostic test 214 is initiated. In one embodiment, the diagnostic test is similar to the diagnostic test 207. The driver register is loaded with alternating binary one and zero values and forwarded through the output buffer to an input of the input differential amplifier. Subsequently, the driver register is serially unloaded at the rising edge of the test clock 128 and applied to an input of the input differential amplifier 122 via the pass gate 140. The output of the input differential amplifier is sampled at the falling edge of the test clock and loaded into the compare register via the pass gate 122. Finally, a XOR operation on each corresponding bit of the compare register and driver register is performed and the result is stored in the status register. Thus, the existence of a pass condition for every bit of the status register indicates the absence of any gross stuck at faults in the output stage of the input/output buffer 100. Also, the input/output buffer 100 fails either or both of the VOH and VOL specifications.

FIG. 3 illustrates a flowchart 300 in accordance with an embodiment. The flowchart illustrates one embodiment of a sequential pattern of testing and diagnostics of an input/output buffer of an integrated device. In one embodiment, flowchart 300 is similar to flowchart 200 of FIG. 2 except for a diagnostic test 314. The diagnostic test 314 utilizes a prior art method of ACIOloopback to verify the output stage of the input/output buffer 100. For example, the ACIOLoopback test analyzes the time needed for various output bits to propagate through the output stage. Based on the difference in time between the various output bits, the output bits that require a longer time to propagate indicate a possible gross stuck at fault.

While the claimed subject matter has been described with reference to specific modes and embodiments, for ease of explanation and understanding, those skilled in the art will appreciate that the claimed subject matter is not necessarily limited to the particular features shown herein, and that the claimed subject matter may be practiced in a variety of ways that fall under the scope and spirit of this disclosure. The claimed subject matter is, therefore, to be afforded the fullest allowable scope of the claims that follow.

1. A method for testing an integrated device comprising:
receiving a signal to enable self test logic; and
comparing a reference level to a first value stored in a first register during a self-test mode of operation of the integrated device.

2. The method of claim 1 further comprising:
forwarding a second value from a first register to a second register via an input differential amplifier if there was a miscompare between the reference level and the first value in the first register; and
comparing the received second value in the second register to the second value in the first register.

3. The method of claim 1 wherein the self-test mode of operation is a built in self test mode.

4. The method of claim 1 wherein the signal is a private Joint Test Action Group (JTAG) instruction.

5. The method of claim 1 wherein the signal is a functional pin of the integrated device.

6. The method of claim 1 wherein the reference level is at least one of a voltage input high (VIH),), a voltage input low (VIL), a voltage output high (VOH), a voltage output low (VOL), a current output low (IOL), and a current output high (IOH).

7. An integrated device comprising:
a logic to enable a comparison of at least one reference level to a first value in a first register during a self-test mode of operation for the integrated device in response to a signal.

8. The integrated device of claim 7 further comprising:
the logic to forward a second value from a first register to a second register via an input differential amplifier if there was a miscompare between the reference level and the first value in the first register; and
the logic to compare the received second value in the second register to the second value in the first register.

9. The integrated device of claim 7 wherein the self-test mode of operation is a built in self test mode.

10. The integrated device of claim 7 wherein the signal is a private Joint Test Action Group (JTAG) instruction.

11. The integrated device of claim 7 wherein the signal is a functional pin of the integrated device.

12. The integrated device of claim 7 wherein the reference level is at least one of a voltage input high (VIH),), a voltage input low (VIL), a voltage output high (VOH), a voltage output low (VOL), a current output low (IOL), and a current output high (IOH).

13. An article comprising:
a storage medium having stored thereon instructions, that, when executed by a computing platform, result in testing of an integrated device by:
comparing a reference level of the integrated device to a first value stored in a first register, coupled to the integrated device, during a self test mode of operation of the integrated device.

14. The article of claim 13, wherein said storage medium further has stored instructions thereon that, when executed, result in:
forwarding a second value from a first register to a second register, coupled to the integrated device, via an input differential amplifier if there was a miscompare between the reference level and the first value in the first register; and
comparing the received second value in the second register to the second value in the first register.

15. The article of claim 13, wherein said voltage reference level is one of a voltage input high (VIH), a voltage input low (VIL), a voltage output high (VOH), a voltage output low (VOL), a current output low (IOL), and a current output high (IOH).
